(19) United States
(12) Patent Application Publication
(10) Pub. No.: US 2023/0246074 A1
(43) Pub. Date: Aug. 3, 2023

(54) GRAPHENE TRANSISTOR

(71) Applicant: KABUSHIKI KAISHA TOSHIBA, Tokyo (JP)

(72) Inventors: Hideyuki TOMIZAWA, Ota Gumma (JP); Akiko YUZAWA, Minato Tokyo (JP); Yoshiaki SUGIZAKI, Fujisawa Kanagawa (JP); Tatsuro SAITO, Kawasaki Kanagawa (JP)

(73) Assignee: KABUSHIKI KAISHA TOSHIBA, Tokyo (JP)

(21) Appl. No.: 17/822,905

(22) Filed: Aug. 29, 2022

(30) Foreign Application Priority Data
Feb. 1, 2022 (JP) 2022-013934

(51) Int. Cl. H01L 29/16; H01L 29/66; H01L 21/02

(52) U.S. Cl. CPC H01L 29/1606; H01L 21/02527; H01L 29/66037

(57) ABSTRACT

A graphene transistor includes an insulating film extending in a first direction and a second direction, the second direction crossing the first direction; graphene located on the insulating film, the graphene including a first opening and a second opening separated from each other in the first direction; a first electrode, the first electrode contacting an upper surface of the graphene, contacting an edge of the graphene positioned in the first opening, and contacting the insulating film in the first opening; and a second electrode, the second electrode contacting the upper surface of the graphene, contacting an edge of the graphene positioned in the second opening, and contacting the insulating film in the second opening.

### CROSS-REFERENCE TO RELATED APPLICATION

This application is based upon and claims the benefit of priority from Japanese Patent Application No.2022-013934, filed on Feb. 1, 2022; the entire contents of which are incorporated herein by reference.

### FIELD

Embodiments described herein relate generally to a graphene transistor.

### BACKGROUND

The contact resistance between a metal and an edge of graphene is known to be less than the contact resistance between the metal and a surface (the upper surface or the lower surface) of the graphene. The contact area between the metal and the graphene edge can be increased by increasing the size of the graphene. However, this may cause an increase of the transistor size.

### BRIEF DESCRIPTION OF THE DRAWINGS

FIG. 1 is a schematic top view of a graphene transistor of a first embodiment;

FIG. 2 is an A-A cross-sectional view of FIG. 1;

FIG. 3 is a schematic top view of a graphene transistor of a second embodiment;

FIG. 4 is a schematic top view of a graphene transistor of a third embodiment; and

FIG. 5 is an enlarged cross-sectional view of portion A of FIG. 2.

### DETAILED DESCRIPTION

According to one embodiment, a graphene transistor includes an insulating film extending in a first direction and a second direction, the second direction crossing the first direction; graphene located on the insulating film, the graphene including a first opening and a second opening separated from each other in the first direction; a first electrode, the first electrode contacting an upper surface of the graphene, contacting an edge of the graphene positioned in the first opening, and contacting the insulating film in the first opening; and a second electrode, the second electrode contacting the upper surface of the graphene, contacting an edge of the graphene positioned in the second opening, and contacting the insulating film in the second opening.

Embodiments will now be described with reference to the drawings. The same components in the drawings are marked with the same reference numerals.

### First Embodiment

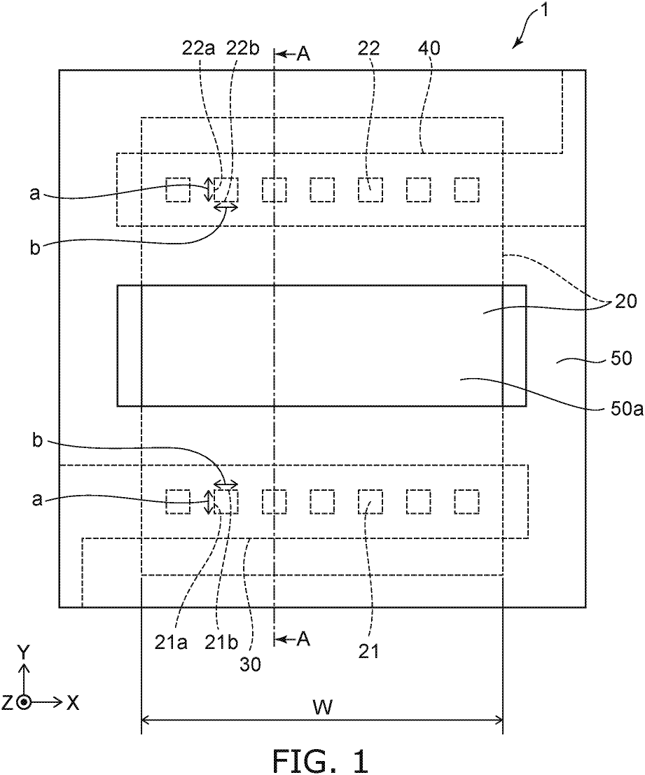

FIG. 1 is a schematic top view of a graphene transistor 1 of a first embodiment.

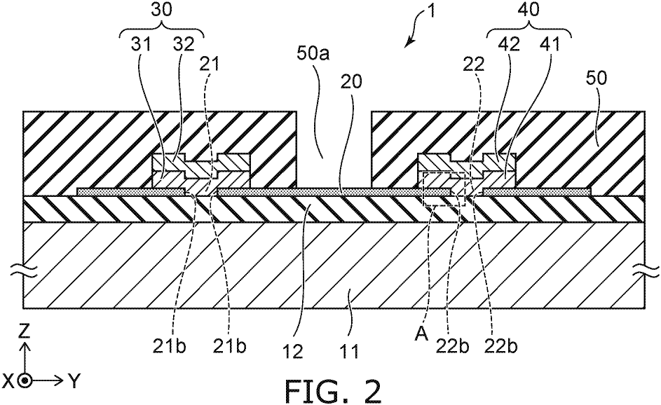

FIG. 2 is an A-A cross-sectional view of FIG. 1.

The graphene transistor 1 includes a substrate 11, an insulating film 12, graphene 20, a first electrode 30, and a second electrode 40. The insulating film 12 is located on the substrate 11; and the substrate 11 and the insulating film 12 contact each other. The graphene 20 is located on the insulating film 12; and the insulating film 12 and the graphene 20 contact each other.

For example, silicon, silicon oxide, glass, or a polymer material can be used as the material of the substrate 11. For example, a silicon oxide film can be used as the insulating film 12. The insulating film 12 also can function as a chemical catalyst for forming the graphene 20. When the substrate 11 is insulative, the substrate 11 also can be used as an insulating film as the foundation of the graphene 20.

The graphene 20 is made of a honeycomb-shaped crystal lattice formed by sp² bonds of carbon atoms. The thickness of the graphene 20 is the thickness of one carbon atom. Or, the thickness of the graphene 20 may be the thickness of not less than two carbon atoms and not more than six carbon atoms.

The graphene 20 includes a lower surface that is at least partially in contact with the insulating film 12, and an upper surface that is positioned at the side opposite to the lower surface and is partially in contact with the first electrode 30 or the second electrode 40. Two directions that are parallel to the upper surface of the graphene 20 and orthogonal to each other are taken as a first direction Y and a second direction X. The substrate 11, the insulating film 12, and the graphene 20 extend along the first and second directions Y and X. One direction from the insulating film 12 toward the graphene 20 is taken as a third direction Z. For convenience of description, among the directions from the insulating film 12 toward the graphene 20, the graphene 20 side (the positive side) is referred to as up, and the insulating film 12 side (the negative side) is referred to as down. Up and down are independent of gravity and the mounting position or mounting angle of the graphene transistor 1. The third direction Z is orthogonal to the first and second directions Y and X. As shown in FIG. 1, the first electrode 30 and the second electrode 40 are separated from each other in the first direction Y. The first electrode 30 and the second electrode 40 are made of a metal material.

As shown in FIG. 2, the first electrode 30 has a stacked structure of a lower layer part 31 and an upper layer part 32. The lower layer part 31 contacts the graphene 20. The upper layer part 32 covers the upper surface of the lower layer part 31. For example, titanium, chrome, nickel, etc., can be used as the material of the lower layer part 31. For example, gold, aluminum, etc., can be used as the material of the upper layer part 32.

The second electrode 40 has a stacked structure of a lower layer part 41 and an upper layer part 42. The lower layer part 41 contacts the graphene 20. The upper layer part 42 covers the upper surface of the lower layer part 41. For example, titanium, chrome, nickel, etc., can be used as the material of the lower layer part 41. For example, gold, aluminum, etc., can be used as the material of the upper layer part 42.

The first electrode 30 and the second electrode 40 are not limited to stacked structures and may have single-layer structures as long as the first electrode 30 and the second electrode 40 can be electrically connected with the graphene 20. The first electrode 30 and the second electrode 40 may have stacked structures of three or more layers.

The graphene 20 includes a first opening 21 and a second opening 22. The first opening 21 and the second opening 22 are separated from each other in the first direction Y. As shown in FIG. 1, multiple first openings 21 are arranged with the second direction X; and multiple second openings 22 are arranged in the second direction X. The first opening 21 and the second opening 22 extend through the graphene 20 in the thickness direction of the graphene 20; and the insulating film 12 is exposed in the first and second openings 21 and 22.

The first electrode 30 is located at the upper surface of the graphene 20 in the region in which the multiple first openings 21 are formed. The first electrode 30 extends in the direction (the second direction X) in which the multiple first openings 21 are arranged at the upper surface of the graphene 20. The first electrode 30 contacts the upper surface of the graphene 20 in the regions in which the multiple first openings 21 are formed. Furthermore, the first electrode 30 is located inside the first openings 21 and contacts the edges (the end parts) of the graphene 20 positioned in the first openings 21 and the insulating film 12 in the first openings 21.

The second electrode 40 is located at the upper surface of the graphene 20 in the region in which the multiple second openings 22 are formed. The second electrode 40 extends in the direction (the second direction X) in which the multiple second openings 22 are arranged at the upper surface of the graphene 20. The second electrode 40 contacts the upper surface of the graphene 20 in the region in which the multiple second openings 22 are formed. Furthermore, the second electrode 40 is located inside the second openings 22 and contacts the edges of the graphene 20 positioned in the second openings 22 and the insulating film 12 in the second openings 22.

According to the first embodiment, the contact resistance between the first electrode 30 and the graphene 20 and the contact resistance between the second electrode 40 and the graphene 20 can be reduced because the first opening 21 and the second opening 22 are provided in the graphene 20, the first electrode 30 is caused to contact the edges of the graphene 20 positioned in the first opening 21, and the second electrode 40 is caused to contact the edge of the graphene 20 positioned in the second opening 22. Rather than the edges of the sides (the outer edges) of the graphene 20, the first electrode 30 and the second electrode 40 contact the edges positioned inside the first opening 21 and the second opening 22 formed in the graphene 20. Therefore, the contact resistance can be reduced by increasing the edge length contacted by the first and second electrodes 30 and 40 while suppressing an increase of the size of the graphene 20 (the transistor size).

In the example shown in FIG. 1, the first opening 21 and the second opening 22 are, for example, quadrilateral. The edges that are positioned in one first opening 21 include two first edges 21a along the first direction Y and two second edges 21b along the second direction X. The edges that are positioned in one second opening 22 include two first edges 22a along the first direction Y and two second edges 22b along the second direction X. The second edge 21b of the first opening 21 and the second edge 22b of the second opening 22 are illustrated in the cross-sectional view of FIG. 2.

When the total length of the edges of the first openings 21 is greater than the length of one side of the graphene 20, the contact resistance between the first electrode 30 and the graphene 20 can be less than that of a structure (a reference example) in which the first electrode 30 simply contacts the edge positioned at one side of the graphene 20. In other words, 2n(a + b) > W is favorable, where W is the width in the second direction X of the graphene 20, a is the length of the first edge 21a positioned in the first opening 21, b is the length of the second edge 21b positioned in the first opening 21, and n is the number of the multiple first openings 21 arranged in the second direction X. In other words, it is favorable for the total value of the lengths of the perimeters of the multiple first openings 21 to be greater than the width in the second direction X of the graphene 20. Thereby, the total length of the edges of the first openings 21 is greater than the length of one side of the graphene 20. The contact resistance between the first electrode 30 and the graphene 20 of the graphene transistor 1 can be less than that of the reference example. In the reference example, the length of the region where the first electrode 30 and the edge of the graphene 20 contact and the length of the region where the second electrode 40 and the edge of the graphene 20 contact each correspond to W.

Similarly, 2n(a + b) > W is favorable, where a is the length of the first edge 22a positioned in the second opening 22, b is the length of the second edge 22b positioned in the second opening 22, and n is the number of the multiple second openings 22 arranged in the second direction X. In other words, it is favorable for the total value of the lengths of the perimeters of the multiple second openings 22 to be greater than the width in the second direction X of the graphene 20.

The graphene transistor 1 can further include an insulative protective film 50. The protective film 50 is located on the first electrode 30, on the second electrode 40, on a part of the graphene 20, and on a part of the insulating film 12 and covers these areas. For example, a resin or an inorganic insulating film can be used as the material of the protective film 50. An opening 50a that exposes a part of the graphene 20 is provided in the protective film 50. A part of the graphene 20 is exposed from under the protective film 50 via the opening 50a in the region between the first electrode 30 and the second electrode 40 in the first direction Y. A part of the graphene 20 functions as a channel region of which the conductivity is changed by an electric field (a voltage) applied via a gate electrode or a reference electrode in a solution. The opening 50a may not be provided as long as an electric field can be applied to a part of the graphene 20.

A current flows between the first electrode 30 and the second electrode 40 via the graphene 20. For example, the graphene transistor 1 can be used as a chemical sensor. For example, probe molecules can be located at the upper surface of the graphene 20 exposed in the opening 50a. For example, when a solution is supplied to the opening 50a, the electron state of the graphene 20 is easily changed by the detection object in the solution approaching the graphene 20, a reaction between the detection object and the probe molecules, etc. A specific detection object can be sensed with high sensitivity by reading the change of such an electrical characteristic of the graphene 20 as the change of the current flowing between the first electrode 30 and the second electrode 40. The potential of the solution also can be controlled by the gate electrode.

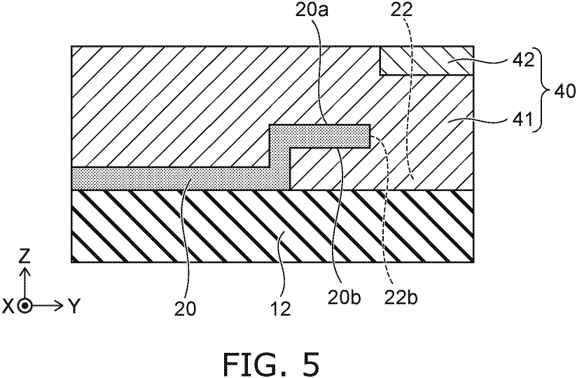

FIG. 5 is an enlarged cross-sectional view of portion A of FIG. 2. The part of the graphene 20 positioned proximate to the opening (in the example of FIG. 5, the second opening 22) easily lifts from the foundation (in this case, the insulating film 12). At the lifted part of the graphene 20, the second electrode 40 also contacts a lower surface 20b of the graphene 20 positioned at the side opposite to an upper surface 20a of the graphene 20; and the second electrode 40 continuously covers the upper surface 20a of the graphene 20, the edge 22b positioned in the second opening 22, and the lower surface 20b of the graphene 20. The contact part between the second electrode 40 and the graphene 20 is stabilized thereby.

Similarly, when the graphene 20 that is positioned proximate to the first opening 21 is lifted, the first electrode 30 also contacts the lower surface 20b positioned at the side opposite to the upper surface 20a of the graphene 20; and the first electrode 30 continuously covers the upper surface 20a of the graphene 20, the edge positioned in the first opening 21, and the lower surface 20b of the graphene 20. The contact part between the first electrode 30 and the graphene 20 is stabilized thereby.

### Second Embodiment

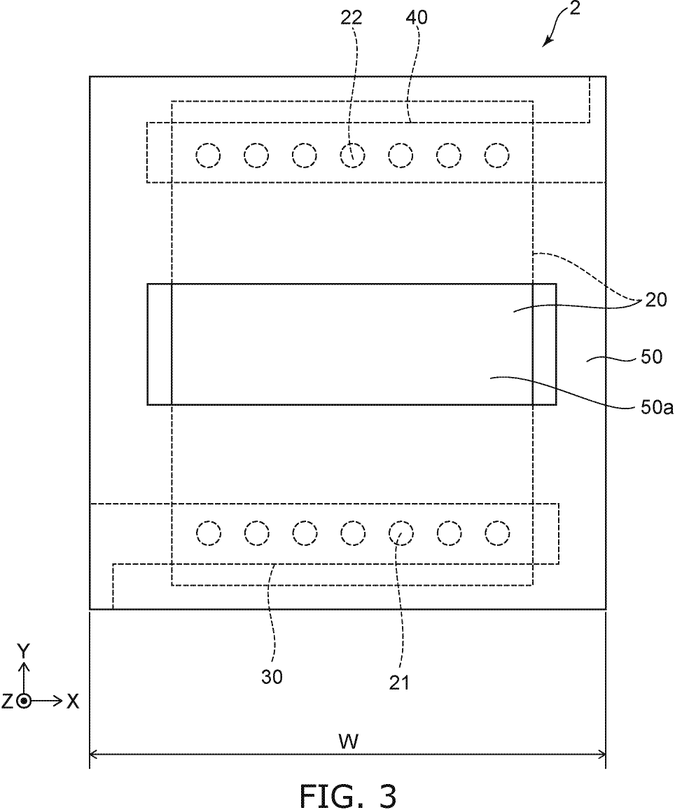

FIG. 3 is a schematic top view of a graphene transistor 2 of a second embodiment.

At least one of the first opening 21 or the second opening 22 can be circular. FIG. 3 shows an example in which the first opening 21 and the second opening 22 are circular. 2πnr > W is favorable, where W is the width in the second direction X of the graphene 20, r is the radius of the first opening 21, and n is the number of the first openings 21. Thereby, the contact resistance between the first electrode 30 and the graphene 20 can be less than that of the reference example described above. Similarly, 2πnr > W is favorable, where r is the radius of the second opening 22, and n is the number of the second openings 22.

### Third Embodiment

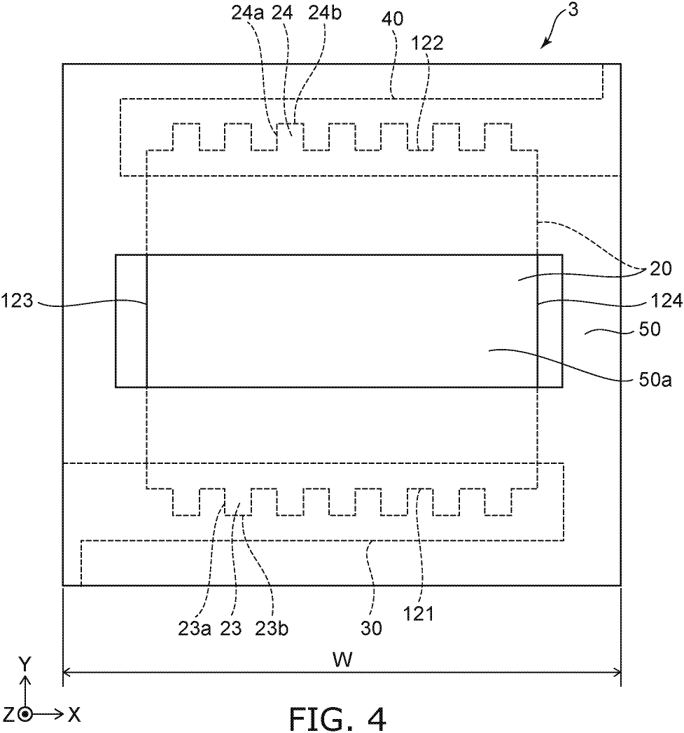

FIG. 4 is a schematic top view of a graphene transistor 3 of a third embodiment.

The exterior shape of the graphene 20 is a quadrilateral that includes four sides (a first side 121, a second side 122, a third side 123, and a fourth side 124). The first side 121 and the second side 122 extend in the second direction X. The third side 123 and the fourth side 124 extend in the first direction Y. The first side 121 and the second side 122 are separated from each other in the first direction Y. The third side 123 and the fourth side 124 are separated from each other in the second direction X. The first side 121, the second side 122, the third side 123, and the fourth side 124 form edges positioned at the outer edge of the graphene 20.

The graphene 20 includes a first protrusion 23 positioned at the first side 121, and a second protrusion 24 positioned at the second side 122. Multiple first protrusions 23 are arranged with the second direction X; and multiple second protrusions 24 are arranged in the second direction X. The first protrusion 23 and the second protrusion 24 are separated from each other in the first direction Y. The first protrusion 23 and the second protrusion 24 protrude in mutually-opposite directions in the first direction Y.

One first protrusion 23 includes two third edges 23a along the first direction Y and one fourth edge 23b along the second direction X. One second protrusion 24 includes two third edges 24a along the first direction Y and one fourth edge 24b along the second direction X.

The first electrode 30 extends in the second direction X at the first side 121 side of the graphene 20. The second electrode 40 extends in the second direction X at the second side 122 side of the graphene 20. The first electrode 30 and the second electrode 40 are separated from each other in the first direction Y.

The first electrode 30 contacts the upper surface of the graphene 20, the edges of the first protrusion 23, and the first side 121. Thereby, the length of the first electrode 30 contacting the edge of the graphene 20 can be greater than that of a configuration in which the first electrode 30 contacts only the first side 121; and the contact resistance between the first electrode 30 and the graphene 20 can be reduced.

The second electrode 40 contacts the upper surface of the graphene 20, the edges of the second protrusion 24, and the second side 122. Thereby, the length of the second electrode 40 contacting the edge of the graphene 20 can be greater than that of a configuration in which the second electrode 40 contacts only the second side 122; and the contact resistance between the second electrode 40 and the graphene 20 can be reduced.

According to the third embodiment as well, the contact resistance can be reduced by increasing the edge length contacted by the first and second electrodes 30 and 40 while suppressing an increase of the size of the graphene 20 (the transistor size).

Various modifications of the first to third embodiments can be implemented.

According to the first and second embodiments, the multiple first openings 21 and the multiple second openings 22 are not necessarily arranged in one column in the second direction X, and may be arranged in multiple columns in the second direction X or arranged in a staggered configuration in the second direction X. Or, the multiple first openings 21 may be positioned at any location overlapping the first electrode 30 in the third direction Z; and the multiple second openings 22 may be positioned at any location overlapping the second electrode 40 in the third direction Z.

According to the first and second embodiments, the multiple first openings 21 and the multiple second openings 22 are not limited to openings of the same shape and size such as quadrilateral, circular, etc. The multiple first openings 21 can be openings of any shape as long as the total value of the lengths of the perimeters of the multiple first openings 21 is greater than the width in the second direction X of the graphene 20. The multiple second openings 22 can be openings of any shape as long as the total value of the lengths of the perimeters of the multiple second openings 22 is greater than the width in the second direction X of the graphene 20.

According to the third embodiment, the edges of the first and second protrusions 23 and 24 are not limited to extending in directions along the first and second directions Y and X. The edges of the first and second protrusions 23 and 24 can include a combination of straight edges, curved edges, etc., extending in any direction in the XY plane.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A graphene transistor, comprising:
an insulating film extending in a first direction and a second direction, the second direction crossing the first direction;
graphene located on the insulating film, the graphene including a first opening and a second opening separated from each other in the first direction;
a first electrode, the first electrode contacting an upper surface of the graphene, contacting an edge of the graphene positioned in the first opening, and contacting the insulating film in the first opening; and
a second electrode, the second electrode contacting the upper surface of the graphene, contacting an edge of the graphene positioned in the second opening, and contacting the insulating film in the second opening.

2. The transistor according to claim 1, wherein
the first electrode and the second electrode are separated from each other in the first direction, and
a plurality of the first openings is arranged in the second direction.

3. The transistor according to claim 2, wherein
the edges include:
a first edge along the first direction; and
a second edge along the second direction, and
$$2 n \left(a + b\right) > W$$
is satisfied, where W is a width in the second direction of the graphene, a is a length of the first edge, b is a length of the second edge, and n is a number of the plurality of first openings.

4. The transistor according to claim 2, wherein
the first opening is circular, and
$$2 π n r > W$$
is satisfied, where W is a width in the second direction of the graphene, r is a radius of the first opening, and n is a number of the plurality of first openings.

5. The transistor according to claim 1, wherein
the first electrode and the second electrode are separated from each other in the first direction, and
a plurality of the second openings is arranged in the second direction.

6. The transistor according to claim 5, wherein
the edges include:
a first edge along the first direction; and
a second edge along the second direction, and
$$2 n \left(a + b\right) > W$$
is satisfied, where W is a width in the second direction of the graphene, a is a length of the first edge, b is a length of the second edge, and n is a number of the plurality of second openings.

7. The transistor according to claim 5, wherein
the second opening is circular, and
$$2 π n r > W$$
is satisfied, where W is a width in the second direction of the graphene, r is a radius of the second opening, and n is a number of the plurality of second openings.

8. The transistor according to claim 1, wherein
a plurality of the first openings is provided, and
a total value of lengths of perimeters of the plurality of first openings is greater than a width in the second direction of the graphene.

9. The transistor according to claim 1, wherein
a plurality of the second openings is provided, and
a total value of lengths of perimeters of the plurality of second openings is greater than a width in the second direction of the graphene.

10. The transistor according to claim 1, wherein
at least one of the first electrode or the second electrode also contacts a lower surface of the graphene positioned at a side opposite to the upper surface, and
the at least one of the first electrode or the second electrode continuously covers the upper surface, the edge, and the lower surface.

11. The transistor according to claim 1, further comprising:
a protective film located on the first electrode, on the second electrode, on a part of the graphene, and on a part of the insulating film,
the protective film being insulative.

12. The transistor according to claim 11, wherein
the protective film includes an opening, and
the graphene is exposed from under the protective film via the opening in a region between the first electrode and the second electrode in the first direction.

13. A graphene transistor, comprising:
an insulating film;
graphene located on the insulating film;
a first electrode; and
a second electrode,
the graphene including
a first protrusion positioned at a first side, and
a second protrusion positioned at a second side,
the first electrode contacting an upper surface of the graphene and an edge of the first protrusion,
the second electrode contacting the upper surface of the graphene and an edge of the second protrusion.

14. The transistor according to claim 13, wherein
the first electrode and the second electrode are separated from each other in a first direction,
the first protrusion and the second protrusion are separated from each other in the first direction,
a plurality of the first protrusions is arranged in a second direction crossing the first direction, and
a plurality of the second protrusions is arranged in the second direction.

15. The transistor according to claim 13, further comprising:
a protective film located on the first electrode, on the second electrode, on a part of the graphene, and on a part of the insulating film,
the protective film being insulative.

16. The transistor according to claim 15, wherein
the protective film includes an opening, and
the graphene is exposed from under the protective film via the opening in a region between the first electrode and the second electrode in the first direction.
